(19) United States
(12) Patent Application Publication
(10) Pub. No.: US 2008/0164514 A1
(43) Pub. Date: Jul. 10, 2008

(54) Semiconductor device having three-demensional transistor and manufacturing method thereof

(75) Inventor: Shigeru Sugioka, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/007,166

(22) Filed: Jan. 7, 2008

(30) Foreign Application Priority Data
Jan. 10, 2007 (JP) 2007-002755

(51) Int. Cl. H01L 29/94; H01L 21/3205

(52) U.S. Cl. 257/328; 438/589; 257/E21.294; 257/E29.345

(57) ABSTRACT

A semiconductor device includes an active region surrounded by an element isolation region; a gate electrode crossing the active region; and at least one slit provided at a boundary portion between the element isolation region and the active region and having a first region covered with the gate electrode and second region not covered with the gate electrode; wherein the first region of the slit is embedded with a conductive material which is the same as that of the gate electrode, and at least an upper part of a second region of the slit is embedded with an insulation material.

### TECHNICAL FIELD

The present invention relates to a semiconductor device and a manufacturing method thereof, and, more particularly to a transistor having a fin-shaped channel region formed perpendicular to a semiconductor substrate, and a method of manufacturing the transistor.

### BACKGROUND OF THE INVENTION

Integration improvement of a semiconductor device has so far been achieved by mainly miniaturizing a transistor. However, according to a normal planar-type transistor, a gate length inevitably becomes short when the miniaturization is progressed. When the gate length becomes short, a subthreshold current increases due to a short-channel effect. To prevent this increase in the subthreshold current, it is necessary to take measures such as to increase the impurity concentration of a channel region.

However, when the impurity concentration of the channel region is increased, junction leakage increases. While the junction leakage does not become a large problem in the transistor used in a logical circuitry, this becomes a cause of significant deterioration in the refresh characteristic in the transistor used in a DRAM (Dynamic Random Access Memory) cell. Therefore, increasing the impurity concentration of the channel region to prevent the short-channel effect is not suitable, particularly for the cell transistor of the DRAM.

As methods of relief the short-channel effect without increasing the impurity concentration of the channel region, several proposals have been made about a technique of three-dimensionally forming a transistor, instead of two-dimensionally forming a transistor like a planar-type transistor.

As one of the three-dimensional transistors, a recess channel (or a trench gate) transistor is known (see Japanese Patent Application Laid-open Nos. H9-232535, 2002-261256, and 2003-78033). The recess channel transistor is a type of transistor having a gate electrode embedded in a trench formed on the semiconductor substrate, with source/drain regions formed at both sides of the trench. When the recess channel transistor is used, on-current flows three dimensionally along the trench, and an effective gate length becomes long. As a result, the short-channel effect can be suppressed while decreasing a plane occupied area.

However, because the gate electrode is embedded into the trench formed in the semiconductor substrate, the recess channel transistor has a problem in that the gate capacitance increases. Further, because the on-current flow three-dimensionally along the trench, there is also a problem that the on-current amount decreases unless a sufficient channel width is secured. Therefore, the recess channel transistor is difficult to be applied to the DRAM cell of which miniaturization has progressed, and a further improvement of the transistor is necessary toward its practical utilization.

As another three-dimensional transistor, a fin transistor is known (see Japanese Patent Application National Publication No. 2006-501672 and Japanese Patent Application Laid-Open Nos. 2005-310921, 2002-118255, 2006-13521, and H5-218415). The fin transistor has a fin-shaped active region formed perpendicular to the semiconductor substrate, with a gate electrode formed to cover the upper surface and both side surfaces of the fin. With this arrangement, the effective channel width increases, and sufficient on-current can be secured. Because the gate electrode covers the upper surface and both side surfaces of the fin, the transistor has very excellent gate controllability. Therefore, the short channel effect can be also effectively suppressed. Because the channel region can be completely depleted by narrowing down the channel width, the improvement of the subthreshold characteristic and the reduction of the offleakage current can be expected.

However, in the fin transistor, the gate capacitance also increases depending on the structure. To decrease the gate capacitance in the fin transistor, it is considered preferable to provide an element isolation region to surround the fin-shaped active region and flatten the surface on which the gate electrode is formed, as shown in FIG. 20 and FIG. 68 of Japanese Patent Application Laid-Open No. 2002-118255, instead of forming the gate electrode to crawl on the three-dimensionally processed semiconductor substrate.

However, when this structure is employed, it becomes necessary to form a slit on both side surfaces of the fin, and embed the inside of the slit with the gate electrode. In this case, a mask pattern for forming the slit is different from that for forming the gate electrode. Therefore, both mask patterns are unavoidably deviated from each other. Depending on a level of this deviation, there is a risk that a cell contact formed thereafter is short-circuited with the gate electrode.

### SUMMARY OF THE INVENTION

It is therefore an object of the present invention to provide a semiconductor device having an improved fin transistor, and a method of manufacturing this transistor.

Another object of the present invention is to provide a semiconductor device having a fin transistor that prevents a short-circuiting between a cell contact and a gate electrode, and a method of manufacturing this transistor.

Still another object of the present invention is to provide a semiconductor device having a fin transistor that decreases a parasitic capacitance of a gate electrode and GIDL (Gate Induced Drain Leakage-current) and a method of manufacturing this transistor.

The above and other objects of the present invention can be accomplished by a semiconductor device comprising: an active region surrounded by an element isolation region, at least one slit being provided at a boundary portion between the element isolation region and the active region; and a gate electrode crossing the active region and the slit, wherein the slit has a first region covered with the gate electrode and a second region not covered with the gate electrode, the first region of the slit is embedded with a conductive material which is the same as that of the gate electrode, and at least an upper part of the second region of the slit is embedded with an insulation material.

The above and other objects of the present invention can also be accomplished by a method of manufacturing a semiconductor device comprising: a first step for forming an active region surrounded by an element isolation region; a second step for forming a slit on a boundary portion between the element isolation region and the active region; a third step for depositing a gate electrode material on at least the active region and the inside of the slit; a fourth step for patterning the gate electrode material to form a gate electrode crossing the active region and to form a cavity in a part of the slit; and a fifth step for embedding the cavity with an insulation material.

As described above, according to the present invention, a part of the slit is not covered by the gate electrode, and this region is embedded with an insulation material. Accordingly, a short-circuiting with the cell contact to be formed thereafter can be prevented. Therefore, reliability of the fin transistor can be increased. Because the parasitic capacitance formed between the gate electrode and the diffusion layer can be decreased, a speed of the switch operation can be increased. Further, because the electric-field intensity between the gate electrode and the diffusion layer can be relaxed, the GIDL can be decreased.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic perspective view for explaining a structure of principal part of a semiconductor device according to a first embodiment of the present invention;

FIG. 2 is a top plan view for explaining a structure of principal part of the semiconductor device according to the first embodiment of the present invention;

FIGS. 3A to 3D are process drawings for explaining one process (patterning of a pad oxide film 101 and a silicon nitride film 102) of the method of manufacturing the semiconductor device according to the first embodiment;

FIGS. 4A to 4D are process drawings for explaining one process (formation of a trench 13t for STI) of the method of manufacturing the semiconductor device according to the first embodiment;

FIGS. 5A to 5D are process drawings for explaining one process (formation of a silicon oxide film 103) of the method of manufacturing the semiconductor device according to the first embodiment;

FIGS. 6A to 6D are process drawings for explaining one process (formation of an opening 104) of the method of manufacturing the semiconductor device according to the first embodiment;

FIGS. 7A to 7D are process drawings for explaining one process (formation of a silicon nitride film 105) of the method of manufacturing the semiconductor device according to the first embodiment;

FIGS. 8A to 8D are process drawings for explaining one process (formation of a silicon oxide film 106) of the method of manufacturing the semiconductor device according to the first embodiment;

FIGS. 9A to 9D are process drawings for explaining one process (formation of a photoresist 107) of the method of manufacturing the semiconductor device according to the first embodiment;

FIGS. 10A to 10D are process drawings for explaining one process (formation of a slit 105a) of the method of manufacturing the semiconductor device according to the first embodiment;

FIGS. 11A to 11D are process drawings for explaining one process (formation of a slit 20) of the method of manufacturing the semiconductor device according to the first embodiment;

FIGS. 12A to 12D are process drawings for explaining one process (removal of the silicon oxide film 103, 106 and the silicon nitride film 105) of the method of manufacturing the semiconductor device according to the first embodiment;

FIGS. 13A to 13D are process drawings for explaining one process (formation of a DOPOS film 111, a silicon nitride film 112 and a silicon oxide film 113) of the method of manufacturing the semiconductor device according to the first embodiment;

FIGS. 14A to 14D are process drawings for explaining one process (formation of a photoresist 114) of the method of manufacturing the semiconductor device according to the first embodiment;

FIGS. 15A to 15D are process drawings for explaining one process (formation of a gate electrode 12) of the method of manufacturing the semiconductor device according to the first embodiment;

FIGS. 16A to 16D are process drawings for explaining one process (formation of a sidewall insulation film 115) of the method of manufacturing the semiconductor device according to the first embodiment;

FIGS. 17A to 17D are process drawings for explaining one process (formation of an interlayer insulation film 116) of the method of manufacturing the semiconductor device according to the first embodiment;

FIGS. 18A to 18D are process drawings for explaining one process (formation of a cell contact plug 118) of the method of manufacturing the semiconductor device according to the first embodiment;

FIGS. 19A to 19D are process drawings for explaining one process (formation of a bit contact plug 119, a bit line 120 and a memory cell capacitor 121) of the method of manufacturing the semiconductor device according to the first embodiment;

FIG. 20 is a schematic perspective view for explaining a structure of principal parts of a semiconductor device according to the second embodiment of the present invention; and

FIG. 21 is a top plan view for explaining a structure of principal parts of the semiconductor device according to the second embodiment.

### DETAILED DESCRIPTION OF THE EMBODIMENTS

Preferred embodiments of the present invention will now be explained below in detail with reference to the accompanying drawings.

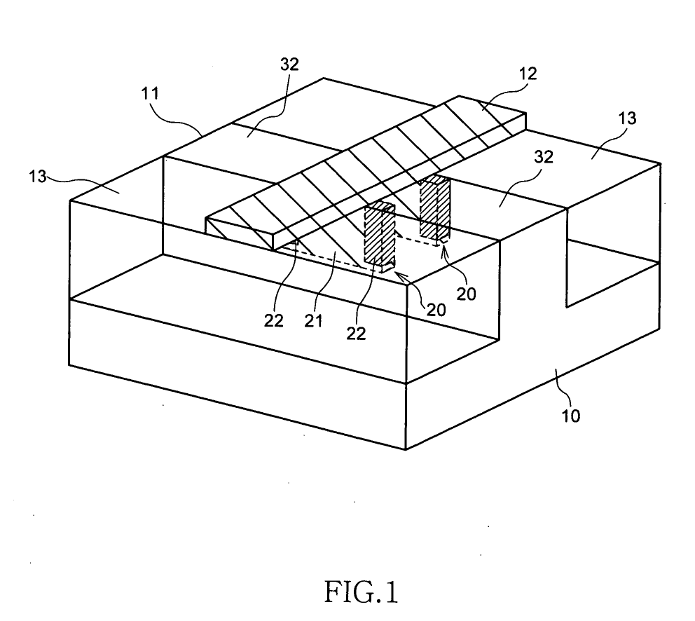

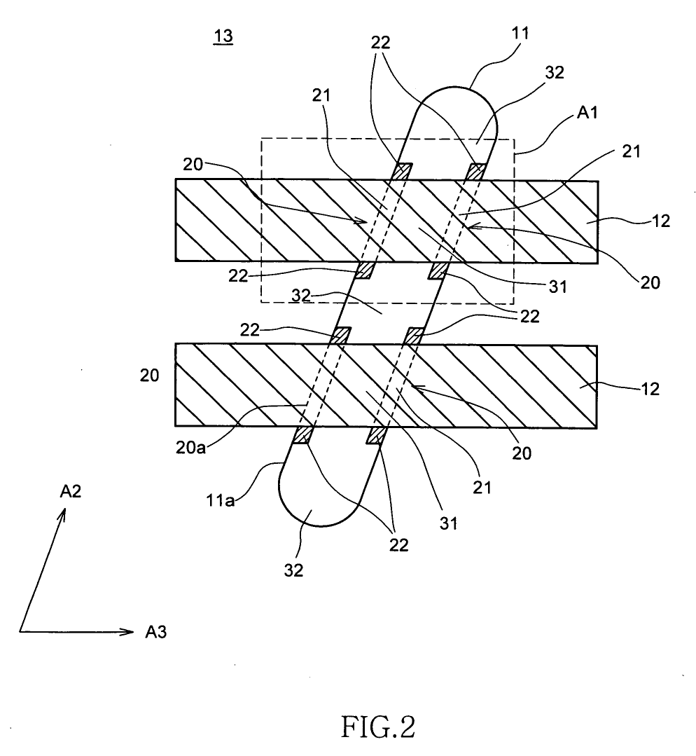

FIG. 1 and FIG. 2 are a schematic perspective view and a top plan view, respectively, for explaining a structure of principal parts of a semiconductor device according to a first embodiment of the present invention. FIG. 1 and FIG. 2 show only main constituent elements by considering easiness of viewing these drawings, and a part of constituent elements such as a sidewall insulation film is omitted. FIG. 1 is a perspective view corresponding to a region A1 shown in FIG. 2.

As shown in FIG. 1 and FIG. 2, the semiconductor device according to the first embodiment includes an active region 11 as a part of a semiconductor substrate 10, and a gate electrode 12 crossing the active region 11. The active region 11 is surrounded by an element isolation region 13, and a longitudinal direction of the active region 11 extends to a direction A2 shown in FIG. 2. On the other hand, the gate electrode 12 extends to a direction of A3 shown in FIG. 2. Preferably, the element isolation region 13 has an STI (Shallow Trench Isolation) structure.

In the example shown in FIG. 2, two gate electrodes 12 cross on one active region 11. This is the structure obtained when the present invention is applied to a memory cell transistor of a DRAM. The present invention is not limited to this structure. Therefore, the number of the gate electrode 12 crossing the active region 11 may be one or three or more.

As shown in FIG. 1, the active region 11 has a fin shape having a part of the semiconductor substrate 10 standing out vertically. However, in the first embodiment, the active region 11 is surrounded by the element isolation region 13. Accordingly, the upper surface of the active region 11 and the upper surface of the element isolation region 13 constitute substantially the same flat surface. Therefore, the formed surface of the gate electrode 12 is substantially flat.

According to the first embodiment, slits 20 extending to the direction of A2 are provided at a boundary between the active region 11 and the element isolation region 13. Two slits 20 are provided for one gate electrode 12. Therefore, a pair of slits 20 is laid out in parallel in the direction of A3.

In the region where the slits 20 are formed, the width of the active region 11 in the direction of A3 is small. Specifically, the slits 20 are formed to bite into the active region 11. Accordingly, a boundary surface 11a between the active region 11 and the element isolation region 13 and a boundary surface 20a between the slits 20 and the element isolation region 13 constitute substantially the same plane surface.

The length of each slit 20 in the direction of A2 is set larger than the width of the gate electrode 12 in the direction of A2. Accordingly, the slit 20 includes a first region 21 covered with the gate electrode 12, and a second region 22 not covered with the gate electrode 12. In the first embodiment, the gate electrode 12 crosses the slits 20 over the whole width in the direction of A2. Accordingly, the slit 20 includes the second regions 22 at its both sides in the direction of A2 from the viewpoint of the gate electrode 12.

A conductive material which is the same as that of the gate electrode 12 is embedded in the first region 21 of the slit 20, thereby constituting a part of the gate electrode 12 (branch part of the gate electrode). As described above, two slits 20 are provided for one gate electrode 12. Therefore, a region sandwiched by the two branch parts of the active region 11 functions as a fin-shaped channel region 31. Both-side regions of the active region 11 in the direction of A2 from the viewpoint of the gate electrode 12 function as source/drain regions 32 including an impurity diffusion layer. Therefore, the width of the source/drain region 32 in the direction of A3 is larger than the width of the channel region 31 in the direction of A3.

Preferably, the channel region 31 has a smaller width in the direction of A3 (planarly-viewed gate width) than a length (gate length) in the direction of A2. This is because when a planarly-viewed gate width (W) is shorter than a gate length (Lg) (Lg>W), the short-channel effect can be suppressed sufficiently. When the planarly-viewed gate width is small, on-current also flows to the side surface parts of the channel region 31, and the effective channel width becomes large. Therefore, even when the planarly-viewed gate width is small, sufficient on-current can be secured. However, when the planarly-viewed gate width is decreased to a few nm by thinning the fin, a threshold voltage is anticipated to rise due to the quantum effect, resulting in an anticipated decrease in the switching speed and an anticipated increase in power consumption. Accordingly, a planarly-viewed gate width (thickness of the fin) is preferably set equal to or higher than 10 nm.

On the other hand, an insulation material is embedded in the upper part of the second region 22 of the slit 20. This insulation material includes the same insulation material as that of a sidewall insulation film (not shown) covering the sidewall of the gate electrode 12. A conductive material which is the same as that of the gate electrode 12 is embedded in the lower part of the second region 22, thereby constituting a part of the gate electrode 12 (branch part of the gate electrode). In the present invention, it is not essential to have the conductive material embedded in the lower part of the second region 22, and it is sufficient that the insulation material is embedded in at least the upper part of the second region 22.

The above explains the structure of the principal parts of the semiconductor device according to the first embodiment. Based on this structure, the on-current of the transistor flows to the upper surface and both side surfaces of the channel region. Therefore, high on-current can be secured while decreasing the sizes of the plane surface. Because the second region 22 of the slit 20 not covered with the gate electrode 12 is embedded with an insulation material, it also becomes possible to prevent the short-circuiting between the contact (the cell contact) to be connected to the source/drain region 32 and the gate electrode 12.

Further, because the parasitic capacitance formed between the gate electrode 12 and the source/drain region 32 can be decreased, the speed of a memory operation can be increased. Because the electric-field intensity between the gate electrode 12 and the source/drain region 32 can be mitigated, the GIDL can be also decreased.

A method of manufacturing the semiconductor device according to the first embodiment is explained next.

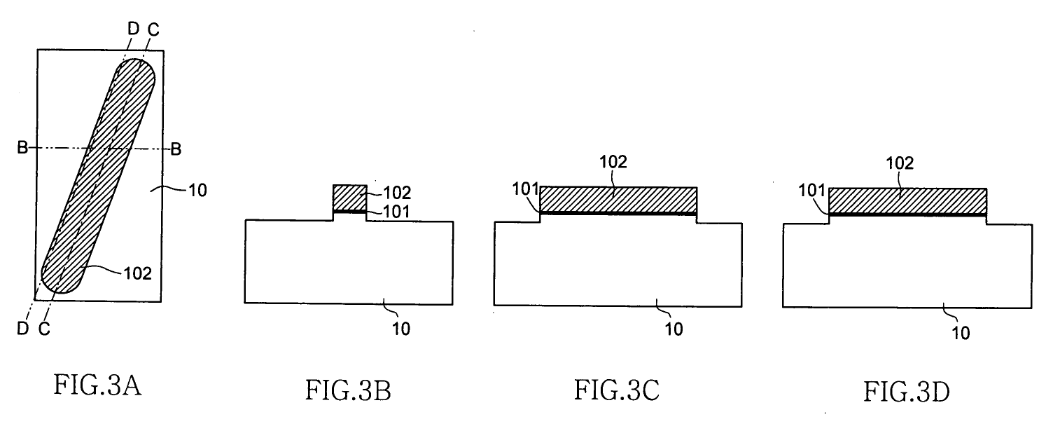

FIGS. 3A to 3D to FIGS. 19A to 19D are process drawings for explaining the method of manufacturing the semiconductor device according to the first embodiment. In these drawings, A is an approximate top plan view, B is an approximate cross-sectional view along a line B-B shown in each A, C is an approximate cross-sectional view along a line C-C shown in each A, and D is an approximate cross-sectional view along a line D-D shown in each A.

First, as shown in FIG. 3A to FIG. 3D, a pad oxide film 101 having a thickness of about 9 nm and a silicon nitride film 102 having a thickness of about 120 nm are formed on the semiconductor substrate 10. Next, the pad oxide film 101 and the silicon nitride film 102 are patterned using a known photolithography technique, thereby forming a planar shape corresponding to the active region 11 (see FIG. 2). Accordingly, the pad oxide film 101 and the silicon nitride film 102 become a mask layer covering a region which becomes the active region. In this case, because overetching is performed, the surface of the semiconductor substrate 10 is also slightly etched.

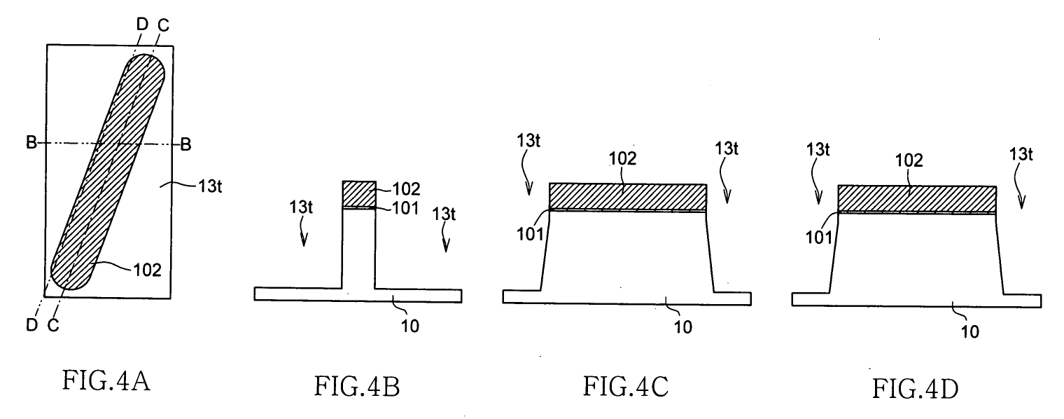

A trench 13t for STI having a depth of about 200 nm is formed in the semiconductor substrate 10, using the silicon nitride film 102 as a mask, as shown in FIG. 4A to FIG. 4D. In this case, the upper surface of the silicon nitride film 102 is also removed by about 50 nm.

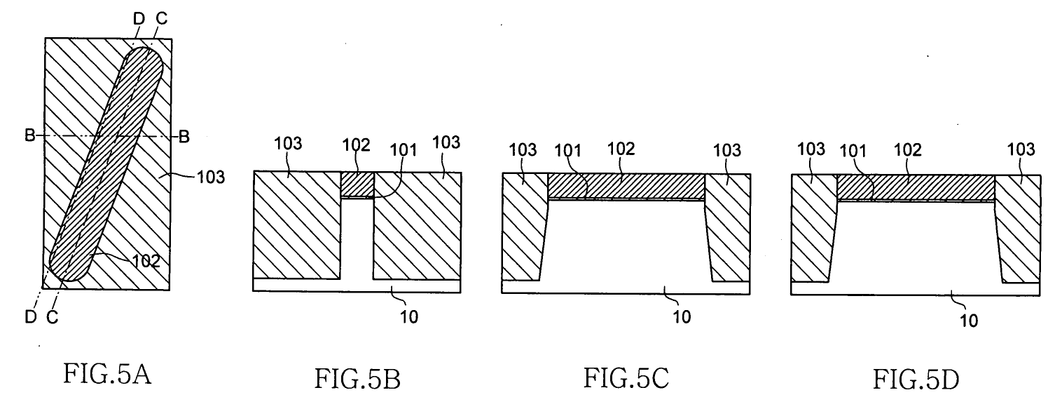

As shown in FIG. 5A to FIG. 5D, a silicon oxide film 103 having a thickness of about 400 nm is formed on the whole surface including the inside of the trench 13t, by the HDP-CVD (High Density Plasma-Chemical Vapor Deposition) method. Thereafter, the silicon oxide film 103 becoming the element isolation region is ground and removed by the CMP (Chemical Mechanical Polishing) method, using the silicon nitride film 102 as a stopper.

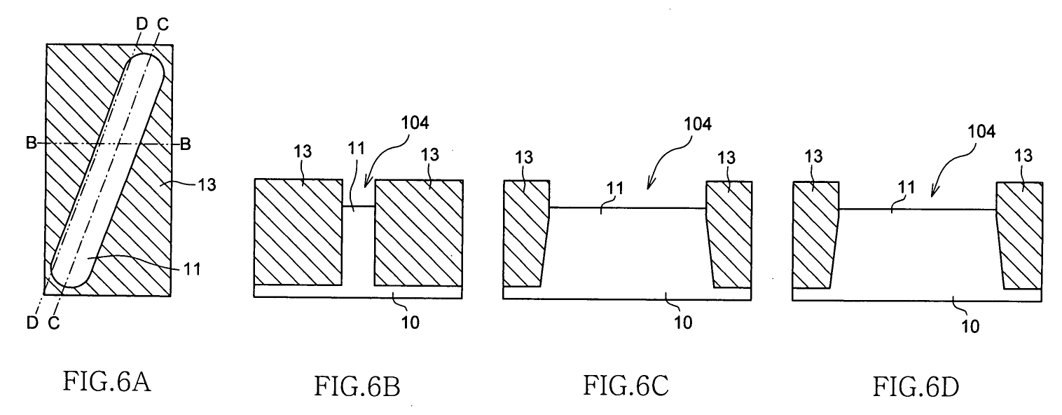

After the CMP ends, a natural oxide film is removed by wet etching. Next, as shown in FIG. 6A to FIG. 6D, the silicon nitride film 102 is removed by wet etching using thermophosphoric acid at about 160° C., and the pad oxide film 101 is removed. Accordingly, the silicon oxide film 103 becomes the element isolation region 13, and the semiconductor substrate 10 surrounded by the element isolation region 13 becomes the active region 11. A step is generated between the element isolation region 13 and the active region 11. Therefore, an opening 104 is formed at a part corresponding to the active region 11. In this case, the height from the surface of the active region 11 to the surface of the element isolation region 13 is set preferably equal to or smaller than 70 nm.

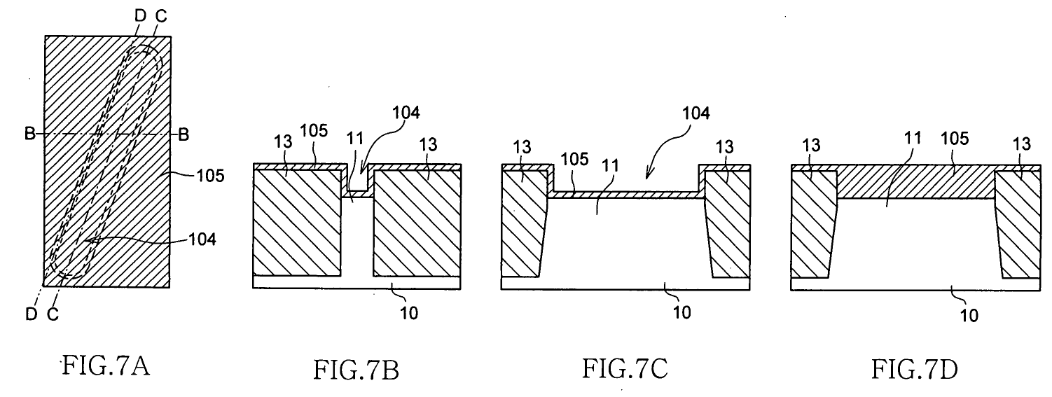

Next, as shown in FIG. 7A to FIG. 7D, a silicon nitride film 105 is formed on the whole surface. A thickness of the silicon nitride film 105 needs to be set equal to or smaller than a half of the width of the active region 11 in the direction of A3 (see FIG. 2), and is set to about 20 to 35 nm, for example. As a result, the sizes of the plane surface of the opening 104 are slightly decreased.

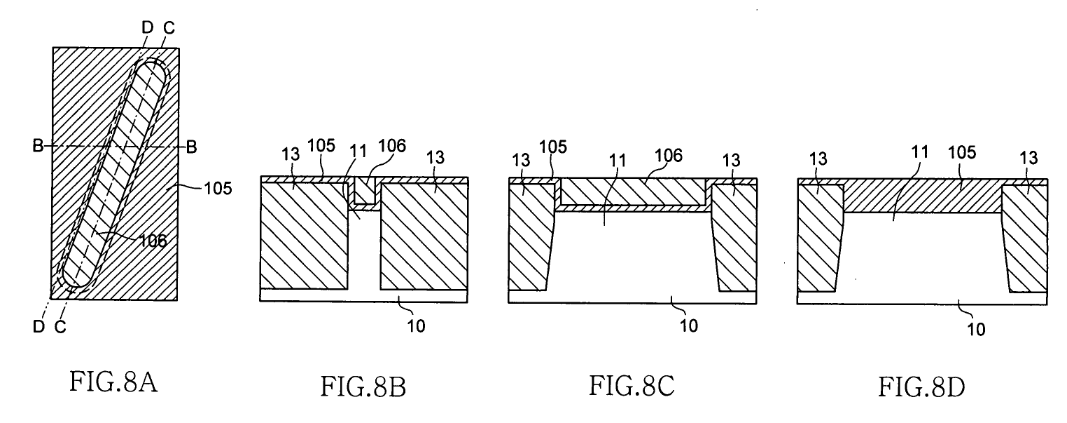

Next, as shown in FIG. 8A to FIG. 8D, a silicon oxide film 106 is formed in a thickness of about 100 nm on the whole surface, and a CMP is performed using the silicon nitride film 105 as a stopper. As a result, the silicon nitride film 106 is embedded in the opening 104.

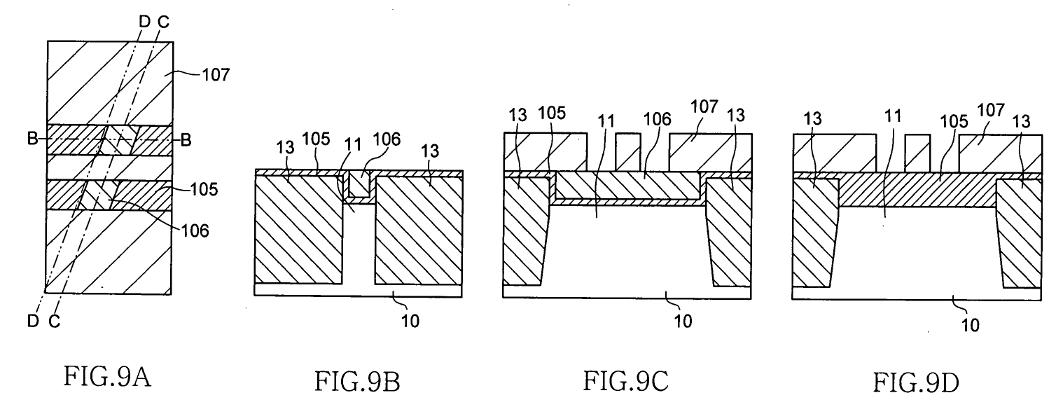

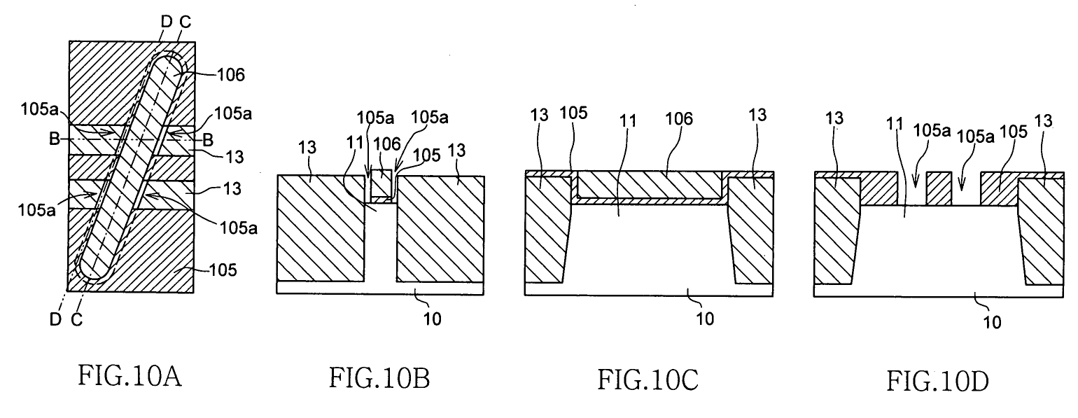

Next, as shown in FIG. 9A to FIG. 9D, a photoresist 107 having an opening with a larger width than that of the gate electrode is formed in the region where the gate electrode 12 (see FIG. 2) is to be formed. As shown in FIG. 10A to FIG. 10D, the silicon nitride film 105 is then selectively removed by dry etching, using the photoresist 107 as a mask. As a result, out of the silicon nitride film 105 formed on the active region 11, a part of the silicon nitride film 105 formed on the step is removed, and a slit 105a corresponding to the film thickness of the silicon nitride film 105 is formed. The semiconductor substrate 10 is exposed to the bottom of the slit 105a. A part of the silicon nitride film 105 formed on the element isolation region 13 is also removed, and the element isolation region 13 is exposed to the removed region.

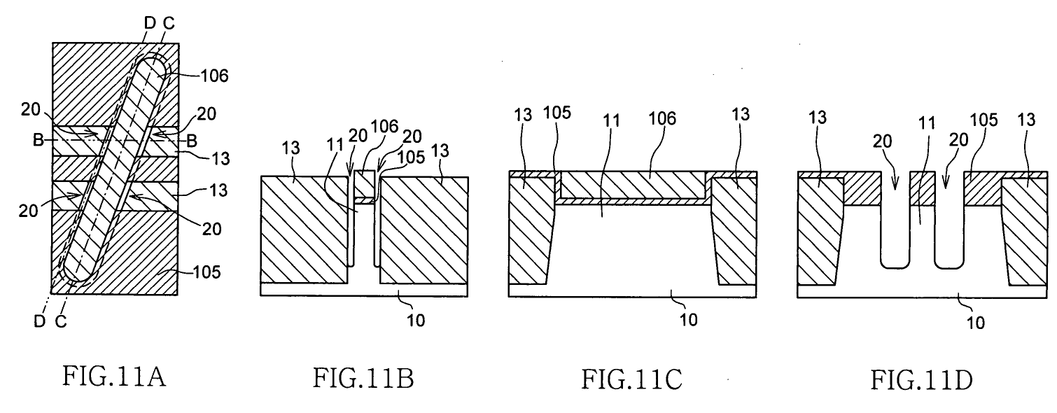

After the photoresist 107 is removed, as shown in FIG. 11A to FIG. 11D, the slit 20 having a depth of about 100 nm is formed in the active region 11, using the element isolation region 13, the silicon oxide film 106 and the silicon nitride film 105 as masks.

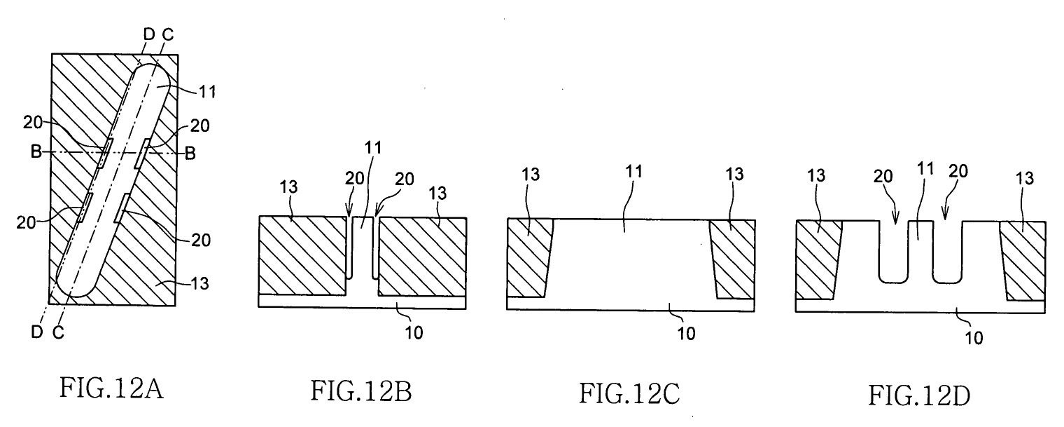

As shown in FIG. 12A to FIG. 12D, the silicon oxide film 106 is removed by wet etching, and thereafter, a sacrifice oxide film (not shown) is formed by performing a sacrifice oxidation. The silicon nitride film 105 is removed by wet etching, and then the silicon oxide film is wet etched, thereby removing the surface of the element isolation region 13, and the silicon oxide film 106 and the sacrifice oxide film.

As a result, the upper surface of the active region 11 and the upper surface of the element isolation region 13 become substantially a flat surface, and four slits 20 are formed to bite into the active region 11.

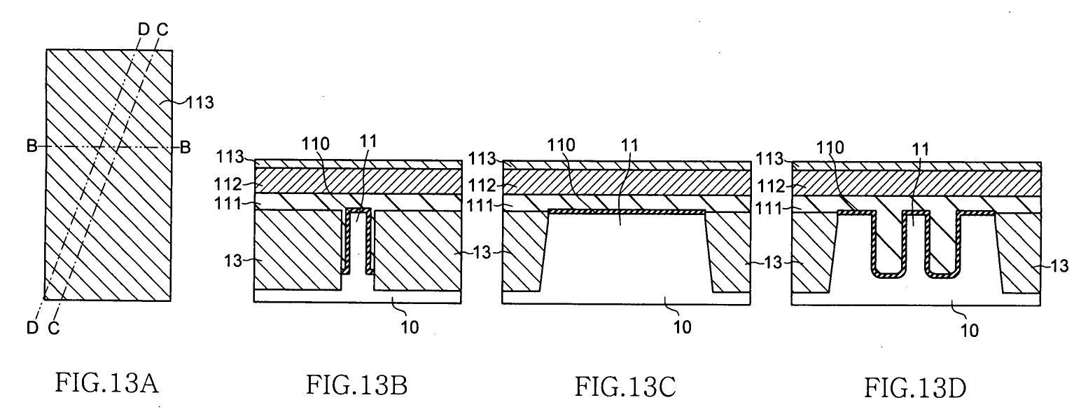

Next, as shown in FIG. 13A to FIG. 13D, a silicon oxide film (gate oxide film) 110 having a thickness of about 6 nm is formed by thermal oxidation. As a result, the upper surface of the active region 11 having the fin shape and the inner surface of the slit 20 are covered with the gate oxide film 110.

Next, a doped polysilicon (DOPOS) film 111 having a thickness of about 100 nm becoming a material of the gate electrode 12 is formed, thereby embedding the inside of the slit 20. Further, a silicon nitride film 112 and a silicon oxide film 113 are formed sequentially on the DOPOS film 111. When the gate electrode 12 is formed in a polymetal structure, a W/WN/WSi film intervenes between the DOPOS film 111 and the silicon nitride film 112, as a laminated film of a tungsten silicide film, a tungsten nitride (WN) film, and a tungsten (W) film. Alternately, the gate electrode 12 can be in a polycide structure.

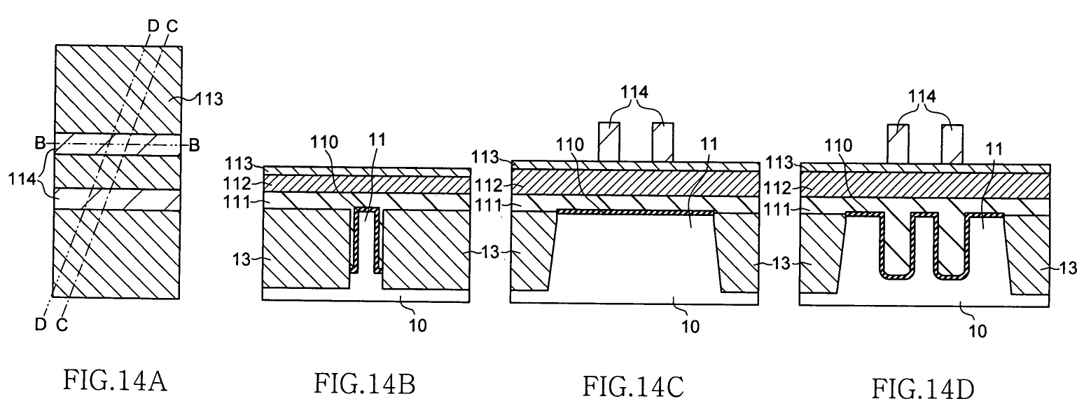

Next, as shown in FIG. 14A to FIG. 14D, a photoresist 114 covering a region on which the gate electrode 12 is to be formed is formed. The region on which the gate electrode 12 is to be formed is the region that crosses the slit 20.

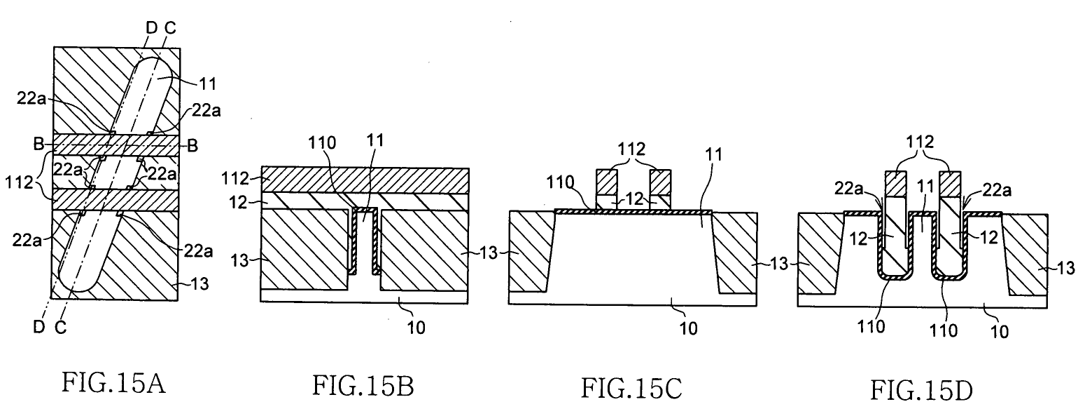

The silicon oxide film 113 and the silicon nitride film 112 are patterned using the photoresistor 114 as a mask, thereby forming a hardmask. As shown in FIG. 15A to FIG. 15D, the DOPOS film 111 is patterned using this hardmask, thereby forming the gate electrode 12.

In patterning the DOPOS film 111, overetching is performed. Accordingly, out of the DOPOS film 111 embedded in the slit 20, the DOPOS film 111 of the region not covered with the gate electrode 12 is dug down. As a result, in the slit 20, a cavity 22a is formed again in the region not covered with the gate electrode 12. In this case, because the surface of the active region 11 is covered with the gate oxide film 110, the area becoming the source/drain region out of the active region 11 is not etched.

When the above patterning is performed, the silicon oxide film 113 also remains when the gate electrode 12 is in the polygate structure. However, when the gate electrode 12 is in the polymetal structure or the polycide structure, the silicon oxide film 113 is removed and the silicon nitride film 112 is exposed, as shown in FIG. 15A to FIG. 15D. The silicon oxide film 113 can remain or can be removed.

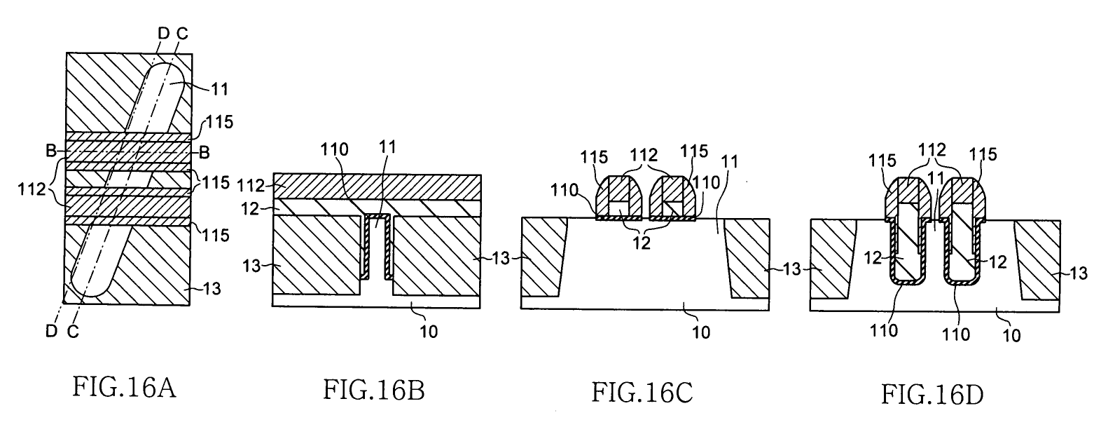

Next, an impurity is ion implanted into the active region 11, using the gate electrode 12 as a mask, and an LDD (Lightly Doped Drain) layer (not shown) is formed. Thereafter, as shown in FIG. 16A to FIG. 16D, sidewall insulation films 115 each having a thickness of 25 to 30 nm are formed on the side surfaces of the gate electrode 12. The sidewall insulation films 115 are formed by first forming a silicon nitride film on the whole surface, and then etching back this silicon nitride film. In this case, the cavity 22a formed on the slit 20 is embedded with the same insulation material (silicon nitride film) as that of the sidewall insulation film 115.

Thereafter, an impurity is ion implanted into the active region 11, using the gate electrode 12 and the sidewall insulation films 115 as masks, thereby forming a source/drain regions 32 (see FIG. 1 and FIG. 2).

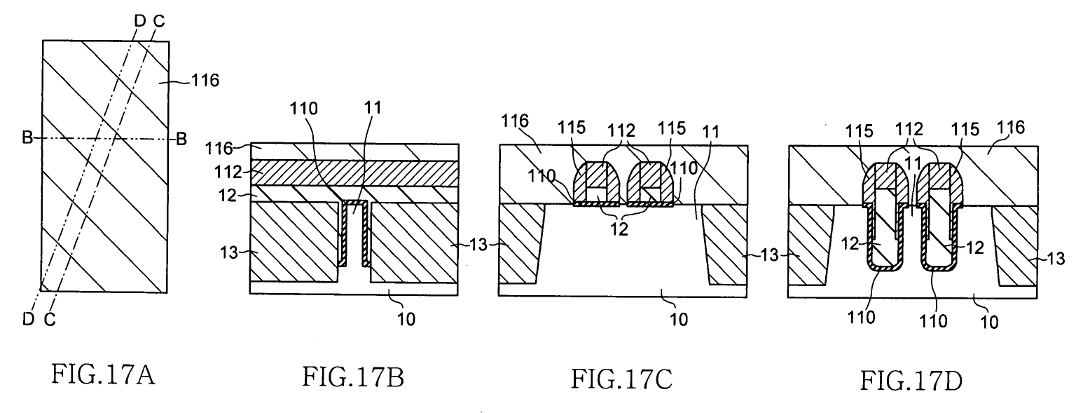

Next, as shown in FIG. 17A to FIG. 17D, a thick interlayer insulation film 116 is formed on the whole surface. For the material of the interlayer insulation film 116, it is necessary to use a material that can be satisfactorily embedded and that can secure an etching rate with the silicon nitride film as the material of the sidewall insulation film 115. This material includes BPSG, for example.

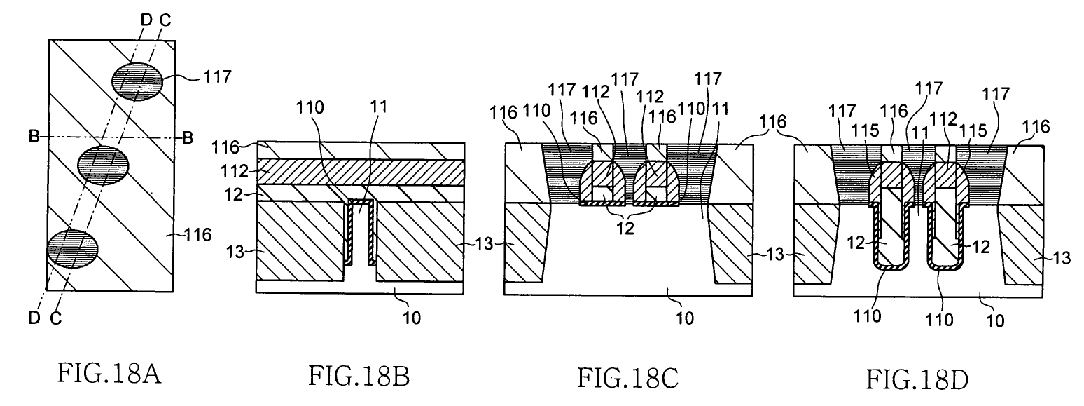

Next, as shown in FIG. 18A to FIG. 18D, contact holes are formed in the interlayer insulation film 116, and cell contact plugs 117 are formed inside the contact holes. In forming the contact hole, the sidewall insulation film 115 becomes a stopper. Therefore, the contact hole can be formed in self-alignment with the source/drain region 32.

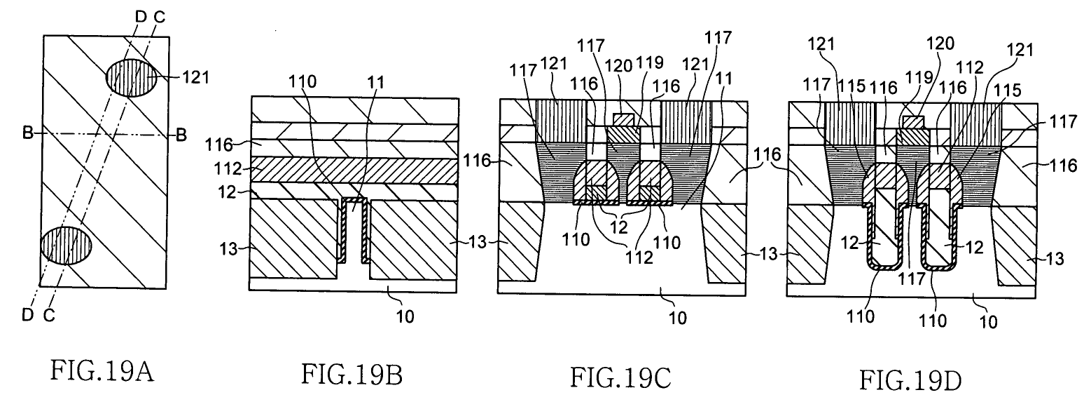

Thereafter, as shown in FIG. 19A to FIG. 19D, a bit contact plug 119 connected to the cell contact plug 117 at the center, and a bit line 120 are formed. Further, a memory cell capacitors 121 and the like connected to cell contact plugs 118 at both ends are formed, thereby completing the DRAM.

As described above, in the method of manufacturing the semiconductor device according to the first embodiment, overetching is performed in patterning the DOPOS film 111. Therefore, the DOPOS film 111 not covered with the gate electrode 12 is dug down, thereby forming the cavity 22a in the slit 20. Thereafter, this cavity 22a is embedded with an insulation material at the time of forming the sidewall insulation film 115. With this arrangement, the DOPOS film 111 is not exposed in the area not covered with the gate electrode 12. Consequently, even when the slit 20 is deviated from the gate electrode 12, the gate electrode 12 and the cell contact plug 118 are not short-circuited.

In the first embodiment, the slit 20 is formed using only the thickness of the silicon nitride film 105 formed on the innerwall part of the opening 104. Therefore, a very thin slit 20 of which resolution exceeds that of the lithography can be formed at a desired position. Consequently, there occurs no deviation at the position where the slit 20 is formed in at least the direction of A3 (see FIG. 2). A distance between adjacent active regions 11 does not need to be increased by estimating a deviation. The gate capacitance can be suppressed to a minimum limit.

A second embodiment of the present invention is explained next.

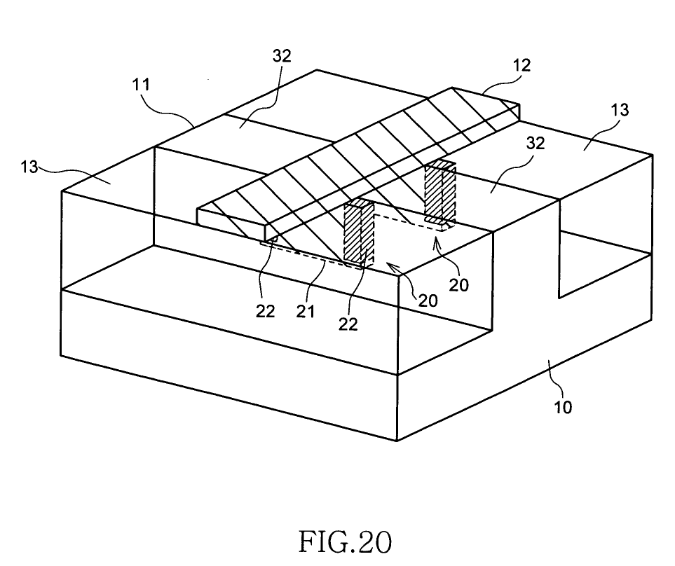

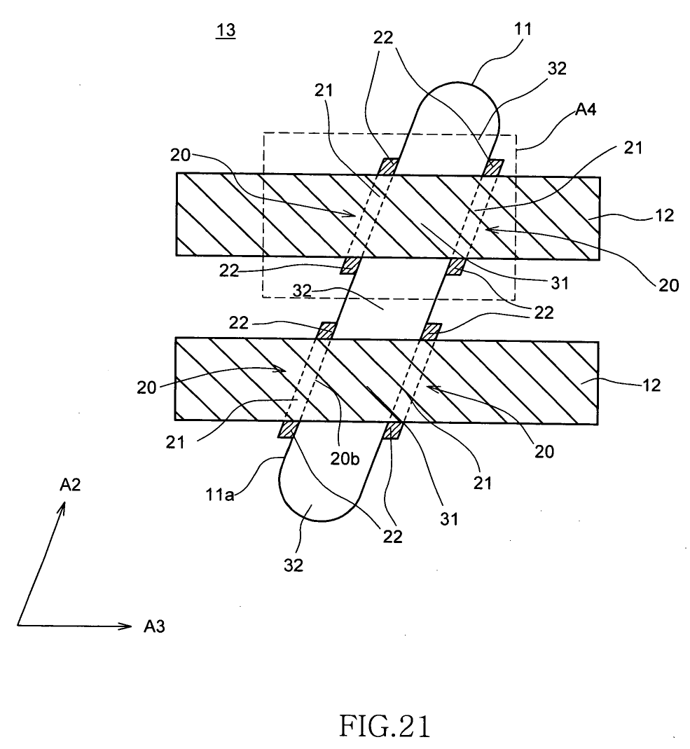

FIG. 20 and FIG. 21 are a schematic perspective view and a top plan view, respectively, for explaining a structure of principal parts of a semiconductor device according to the second embodiment. FIG. 20 and FIG. 21 show only main constituent elements by considering easiness of viewing these drawings, and a part of constituent elements such as a sidewall insulation film is omitted. FIG. 20 is a perspective view corresponding to a region A4 shown in FIG. 21.

As shown in FIG. 20 and FIG. 21, in the second embodiment, the width of the active region 11 in the direction of A3 is substantially constant. In the second embodiment, the slits 20 are not formed to bite into the active region 11, and the slits 20 are formed along the flat side surface of the active region 11. In other words, the slits 20 are formed to bite into the element isolation region 13. With this arrangement, the boundary surface 11a between the active region 11 and the element isolation region 13 and a boundary surface 20b between the active region 11 and the slits 20 constitute substantially the same plane surface.

Other configurations are basically the same as those of the semiconductor device according to the first embodiment explained above. Therefore, like components are denoted by like numerals and explanations thereof will be omitted. The configuration according to the second embodiment can provide the same effects as the first embodiment.

While the method of forming the slits 20 is not particularly limited, the element isolation region 13 can be formed so that the active region 11 becomes higher than the element isolation region 13, in the opposite manner to that according to the first embodiment, for example. According to this method, the sidewall of the silicon nitride film 105 and the like is formed at the element isolation region 13 side from the viewpoint of the boundary between the active region 11 and the element isolation region 13. Therefore, when the element isolation region 13 is etched using this sidewall as a mask, the slits 20 that bite into the element isolation region 13 can be formed.

While the slits 20 can be also formed by the normal lithography, preferably the slits 20 are formed using the thickness of the silicon nitride film 105 formed on the step between the active region 11 and the element isolation region 13, as described above. According to this method, not only a positional deviation of the slits 20 does not occur in the direction of A3, but also the thin slits 20 which the normal lithography cannot achieve can be formed.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

While the application of the present invention to a memory transistor such as a DRAM has been explained in the above embodiments, the application of the present invention is not limited thereto. For example, the invention can be also applied to a memory device other than a DRAM or to a device of a logic system.

While the cavity 22a is embedded simultaneously with the formation of the sidewall insulation film 115 in the embodiments, the cavity 22a can be also embedded using an insulation material different from that of the sidewall insulation film 115.

In the above embodiments, the gate electrode 12 crosses each slit 20 over the whole width in the direction of A2. Accordingly, the second regions 22 of each slit 20 are laid out at its both sides in the direction of A2 from the viewpoint of the gate electrode 12. However, the second regions 22 of each slit 20 are not necessary to be laid out at its both sides in the direction of A2 from the viewpoint of the gate electrode 12. It is sufficient that the second region 22 of each slit 20 is laid out at its at least one side in the direction of A2 from the viewpoint of the gate electrode 12.

While the length of the slit 20 in the direction of A2 is larger than the width of the gate electrode 12 in the direction of A2 in the above embodiments, a size relation is not limited to this in the present invention. As described above, it is sufficient that the second region 22 of the slit 20 is laid out at least at one side in the direction of A2 from the viewpoint of the gate electrode 12.

What is claimed is:

1. A semiconductor device comprising:
an active region surrounded by an element isolation region, at least one slit being provided at a boundary portion between the element isolation region and the active region; and
a gate electrode crossing the active region and the slit,
wherein the slit has a first region covered with the gate electrode and a second region not covered with the gate electrode, the first region of the slit is embedded with a conductive material which is the same as that of the gate electrode, and at least an upper part of the second region of the slit is embedded with an insulation material.

2. The semiconductor device as claimed in claim 1, wherein a lower part of the second region is embedded with a conductive material which is the same as that of the gate electrode.

3. The semiconductor device as claimed in claim 1, further comprising a sidewall insulation film covering at least a sidewall of the gate electrode, wherein the sidewall insulation film is made of the same material as the insulation material.

4. The semiconductor device as claimed in claim 1, wherein a longitudinal direction of the active region and the slit extend to a first direction, and the gate electrode extends to a second direction different from the first direction.

5. The semiconductor device as claimed in claim 4, wherein two slits are provided in parallel, the active region has a region sandwiched between the two slits that functions as a fin-shaped channel region.

6. The semiconductor device as claimed in claim 5, wherein the active region has both-side regions in the first direction from a viewpoint of the gate electrode that function as source/drain regions, and a width of the source/drain region in the second direction is larger than a width of the channel region in the second direction.

7. The semiconductor device as claimed in claim 6, wherein a boundary surface between the active region and the element isolation region and a boundary surface between the slit and the element isolation region constitute substantially the same plane surface.

8. The semiconductor device as claimed in claim 5, wherein a boundary surface between the active region and the element isolation region and a boundary surface between the active region and the slit constitute substantially the same plane surface.

9. The semiconductor device as claimed in claim 5, wherein a width of the channel region in the second direction is smaller than a length of the channel region in the first direction.

10. The semiconductor device as claimed in claim 4, wherein a length of the slit in the first direction is larger than a width of the gate electrode in the first direction.

11. The semiconductor device as claimed in claim 10, wherein the gate electrode crosses the slit over the whole width in the first direction so that the slit has the second regions at both sides in the first direction from the viewpoint of the gate electrode.

12. The semiconductor device as claimed in claim 1, wherein the upper surface of the element isolation region and the upper surface of the active region constitute substantially the same plane surface.

13. A method of manufacturing a semiconductor device comprising:
a first step for forming an active region surrounded by an element isolation region;
a second step for forming a slit on a boundary portion between the element isolation region and the active region;
a third step for depositing a gate electrode material on at least the active region and the inside of the slit;
a fourth step for patterning the gate electrode material to form a gate electrode crossing the active region and to form a cavity in a part of the slit; and
a fifth step for embedding the cavity with an insulation material.

14. The method of manufacturing the semiconductor device as claimed in claim 13, wherein
at the first step, the element isolation region and the active region are formed so that a step portion is formed between the element isolation region and the active region, and
the second step includes a step for forming an insulation film on at least the step portion, a step for removing a part of the insulation film formed on the step portion, and a step for etching a semiconductor substrate by using the remaining insulation film as a part of a mask.

15. The method of manufacturing the semiconductor device as claimed in claim 13, wherein
at the fourth step, the gate electrode material is patterned to form the gate electrode, and thereafter, the cavity is formed by overetching the gate electrode material.

16. The method of manufacturing the semiconductor device as claimed in claim 13, wherein
at the fifth step, the insulation material is formed on the whole surface, and thereafter, the cavity is embedded with an insulation material by etching back the insulation material.
